(19) United States
(12) Patent Application Publication
(10) Pub. No.: US 2007/0063738 A1
(43) Pub. Date: Mar. 22, 2007

(54) CMOS logic circuitry

(76) Inventor: Timothy C. Fischer, Firestone, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/229,287

(22) Filed: Sep. 16, 2005

(51) Int. Cl. H03K 19/094

(52) U.S. Cl. 326/83

(57) ABSTRACT

A complimentary metal oxide semiconductor (CMOS) circuit may include a CMOS output stage comprising at least one p-channel metal oxide semiconductor (PMOS) component and at least one n-channel metal oxide semiconductor (NMOS) component connected in series between first and second voltage rails, a juncture between the at least one PMOS component and at least one NMOS component providing an output. A predriver stage includes first and second predriver paths electrically connected between at least one input and the output stage. The first predriver path is configured to perform a logic function on the at least one input and to provide a first logic signal to an input of the at least one PMOS component. The second predriver path is configured to perform the logic function on the at least one input and to provide a second logic signal to an input of the at least one NMOS component.

### BACKGROUND

Complementary metal-oxide-semiconductor (CMOS) is a process technology that uses p-type and n-type channel devices on the same integrated circuit. Most CMOS circuits contain equal numbers of n and p type transistors. Certain types of CMOS circuits, including complementary CMOS gates (and buffers consisting of series inverters), are inherently power-inefficient because of crossover current that is wasted during switching. For example, in a complementary CMOS gate, one or more inputs connect to a p-channel field effect transistor (PFET) and to an n-channel field effect transistor (NFET). When an input switches low or high causing the output to transition, one FET turns on before the other FET turns off. This latency can generate a large short-circuit current (e.g., from V_{DD} to ground) through the two partially-on FET paths, which is known as crossover current. Crossover current power can range from about 5% to about 15% or more of the total CMOS gate switching power, depending generally on input edge rate.

### BRIEF DESCRIPTION OF THE DRAWINGS

FIG. 1 depicts a schematic illustration of an example of CMOS logic circuit.

FIG. 2 depicts an example of a CMOS logic gate implementing a unary transfer function.

FIG. 3 is a graph depicting a comparison of switching current for a traditional CMOS buffer and the CMOS gate shown in FIG. 2.

FIG. 4 depicts an example of a CMOS logic gate implementing an AND function.

FIG. 5 depicts an example of a CMOS logic gate implementing an OR function.

### DETAILED DESCRIPTION

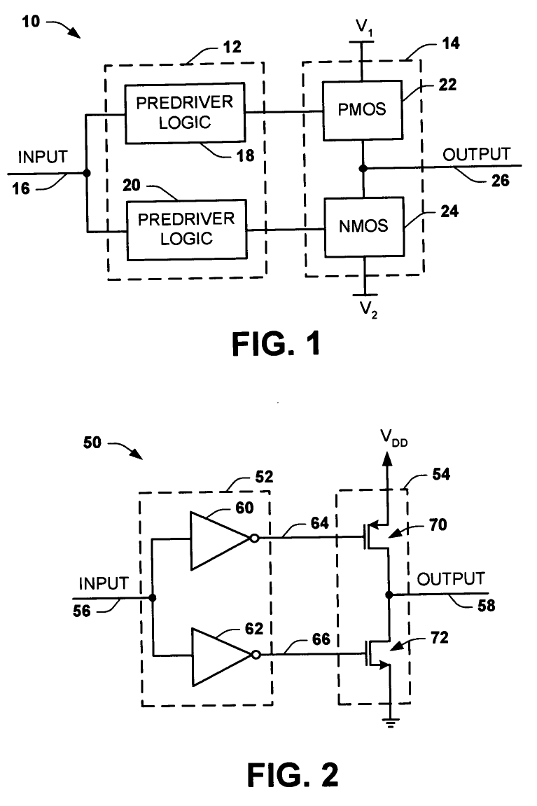

FIG. 1 depicts an example of a complementary metal-oxide-semiconductor (CMOS) logic circuit 10. The circuit 10 includes an input stage 12 and an output stage 14. The input stage 12 receives one or more INPUT signals at a corresponding input 16. The one or more input signals, for instance, correspond to digital data, such as each bit having a defined state high (or logic 1) or low (logic 0). The input stage 12 includes first and second predriver logic paths 18 and 20 that are electrically connected between the input 16 and the output stage 14. The output stage 14 includes one or more p-channel metal oxide semiconductor (PMOS) components 22 and one or more n-channel metal oxide semiconductor (NMOS) component 24. The PMOS and NMOS components 22 and 24 are connected in series between first and second voltage rails, indicated at V₁ and V₂ (e.g., VDD and electrical ground). A juncture between the PMOS and NMOS components 22 and 24 defines an output 26 of the circuit 10 at which a corresponding OUTPUT signal is provided. For example, the PMOS component 22 and the NMOS component can be configured as a push-pull CMOS inverter. Thus, the output stage 14 may correspond to means for inverting logic output signals from the input stage 12 and for providing the OUTPUT signal, which OUTPUT signal is a non-inverted version of the signals provided by the input stage.

Each of the respective predriver logic paths 18 and 20 can be implemented as a gate configured for performing a logic function on the one or more INPUT signals. For purposes of consistency, the circuit 10 and similarly configured circuits may be referred to herein as a pseudo-push-pull CMOS logic gate. As used herein, the terms “gate” and “logic gate” are intended to encompass any type of logic element or combination of logic elements (or other circuit means) that is configured or arranged to implement a function on one or inputs. For example, a gate can correspond to a buffer that is configured to pass an input of one or more bits to an output of the buffer (i.e., implementing a unary transfer function). Alternatively, a gate can be configured to implement Boolean logic functions, such as including, but not limited to AND, OR, exclusive-OR (XOR), and combinations thereof. Thus, these and other types of logic gates can be further combined to implement more complex logic functions on the one or more input signals provided at 16.

The predriver logic paths 18 and 20 drive the output stage 14 according to the logic function implemented by the predriver logic. As an example, the first and second predriver logic paths 18 and 20 can be configured as logically identical paths. By “logically-identical,” it is meant that the each of the paths is configured with an arrangement of complementary devices arranged to perform the same logic function along the respective paths.

As a further example, each of the predriver logic paths 18 and 20 is configured as a CMOS gate that includes at least one p-channel field effect transistor (PFET) and at least one n-channel field effect transistor (NFET). The particular number and arrangement of PFET and NFET devices in each of the predriver logic 18 and 20 will vary upon the desired logic function being performed. For ease of fabrication and simplicity of design, although not by necessity, the same number and type of devices (e.g., one or more p-channel field effect transistors and n-channel field effect transistors) can be used in each of the respective paths 18 and 20. The predriver logic paths 18 and 20 thus may correspond to means for performing a logic function (e.g., inverting logic) on the one or more input signals provided at 16 and for providing corresponding logic signals at respective inputs of the output stage 14.

While each of the predriver logic paths 18 and 20 are logically identical, the predriver logic paths are configured so that the one or more input signals propagate in a speed-skewed manner through the respective paths to the output stage 14. Stated differently, PFET and NFET devices in the predriver logic paths 18 and 20 are varied so that the rise/fall delays the predriver logic are not equal, so that there is differential delay between transitions at the respective outputs of the predriver logic paths. The non-equal rise/fall delays can be achieved, for example, by configuring the predriver logic paths 18 and 20 so as to have different PFET to NFET width ratios. For example, the PFET to NFET width ratio of the predriver logic path 18 (which drives the PMOS component 22) can be greater than the PFET to NFET width ratio of the other predriver logic path 20 (which drives the NMOS component 24). As another example, the PFET to NFET width ratio of the predriver logic path 18 is skewed to be greater than 2:1 and the PFET to NFET width ratio of the other predriver logic path 20 is skewed to be less than 2:1. Other variations of PFET to NFET width ratios can also be utilized in the input stage 12.

By way of example, such a configuration enables the PMOS component 22 to be turned off more quickly than the NMOS component 24 is turned on when the outputs from the predriver logic 18 and 20 transition from logic low to logic high. Similarly, when the outputs from the predriver logic 18 and 20 transition from logic high to logic low, the NMOS component 24 to be turned off more quickly than the PMOS component 22 is turned on. The differential delay the transition at the outputs of the predriver logic paths 18 and 20 may be approximately the same (or it may be different) depending on whether the transition at the outputs from is from low to high or high to low. This skewed switching relationship temporarily induces a small voltage differential between the inputs of the PMOS component 22 and the NMOS component 24. It will be appreciated that even a small voltage difference at the inputs of the PMOS component 22 and the NMOS component 24 is sufficient to reduce crossover current significantly because the overlap between on conditions for the PMOS component 22 and the NMOS component 24 are reduced accordingly.

While this approach modifies the trip point of one or both of the predriver logic 18 and 20, it does not significantly increase the overall gate delay. The reduced crossover current further improves the circuit gain, which sufficiently reduces the delay so as to substantially compensate for the change in the trip point. Additionally, since the total driver load perceived by the input stage 12 remains substantially unchanged relative to a traditional CMOS gate, the total predriver area of the circuit 10 will be nearly identical to the traditional gate, except for being split into the separate predriver logic paths 18 and 20 for driving separate input nodes of the output stage. As a result, an IC incorporating pseudo-push-pull CMOS gate circuitry, such as the type shown and described in FIG. 1, can operate with increased power efficiency relative to another IC implementing traditional CMOS gates.

FIG. 2 depicts an example of a pseudo-push-pull CMOS buffer 50. The buffer 50 includes a predriver input stage 52 that is connected to drive an output stage 54 based on an INPUT signal provided at a corresponding input 56. The output stage 54 is configured to drive an output 58 with an OUTPUT signal based on a logic signal provided by the input stage 52.

The input stage 52 includes a pair of predriver logic paths 60 and 62, each of which is connected to drive a node 64 and 66 at respective inputs of the output stage 54 based on the INPUT signal. Each of the predriver paths 60 and 62 can be logically identical. In the example of FIG. 2, each of the predriver logic paths 60 and 62 include an inverter connected between the input 56 and the respective inputs 64 and 66 of the output stage 54. As an example, the inverters can be configured as a CMOS push-pull inverter that includes a PFET connected in series with an NFET between respective high and low voltage rails (e.g., V_{DD} and electrical ground). Thus, the input stage 52 provides an inverted version of the INPUT signal (i.e., I̅N̅P̅U̅T̅) to each of the nodes 64 and 66 as inputs to of the output stage 54.

The output stage 54 is configured as a push-pull CMOS output driver that inverts the signals provided at 64 and 66 to generate the OUTPUT signal. The output stage 54 includes a PFET 70 connected in series with an NFET 72 between V_{DD} and electrical ground. With the circuit 50 configured as a buffer (implementing a unary transfer function), OUTPUT=INPUT.

The predriver logic paths 60 and 62 are speed-skewed relative to each other so that a transition of the INPUT signal provided at 56 results in delay in the corresponding transition between the output signals at the respective nodes 64 and 66. By way of example, when the INPUT signal switches from high to low, the PFET 70 is turned off more quickly than the NFET 72 is turned on. Conversely, when the INPUT signal switches from low to high, the NFET 72 is turned off more quickly than the PFET 70 is turned on. This switching latency between the output stage FETs induces a small voltage differential between the PFET input 64 and the NFET input 66. This voltage differential between the PFET input 64 and the NFET input 66 is sufficient to mitigate crossover current significantly since the overlapping on state of the PFET 70 and the NFET 72 will be reduced accordingly. For the example of a typical CMOS FET having a gate-to-source threshold voltage (Vₜ) of about 350 mV, a voltage difference between the PFET and NFET gates of approximately 30-50 mV will significantly reduce crossover current. As an example, a savings in average switching power can range from about 15% to approximately 25%, which may vary depending signal edge rates utilized in the circuit 50. The peak switching current also is reduced, which mitigates on-chip switching noise and provides improved signal integrity.

By way of further example, the PFET to NFET width ratio of the predriver logic path 60 can be greater than the PFET to NFET width ratio of the predriver logic path 62 so as to provide desired speed-skewed paths. For instance, the PFET to NFET width ratio of the predriver logic path 60 can be skewed to be greater than 2:1 (e.g., 3:1) and the PFET to NFET width ratio of the other predriver logic path 62 can be skewed to be less than 2:1 (e.g., 1:1). Other variations in the FET dimensions can also be implemented to speed-skew the respective paths 60 and 62. While, for simplicity of explanation, a single-bit buffer is depicted in FIG. 2, it will be appreciated that the approach shown and described herein is equally applicable to performing a unary transfer function for multi-bit input data.

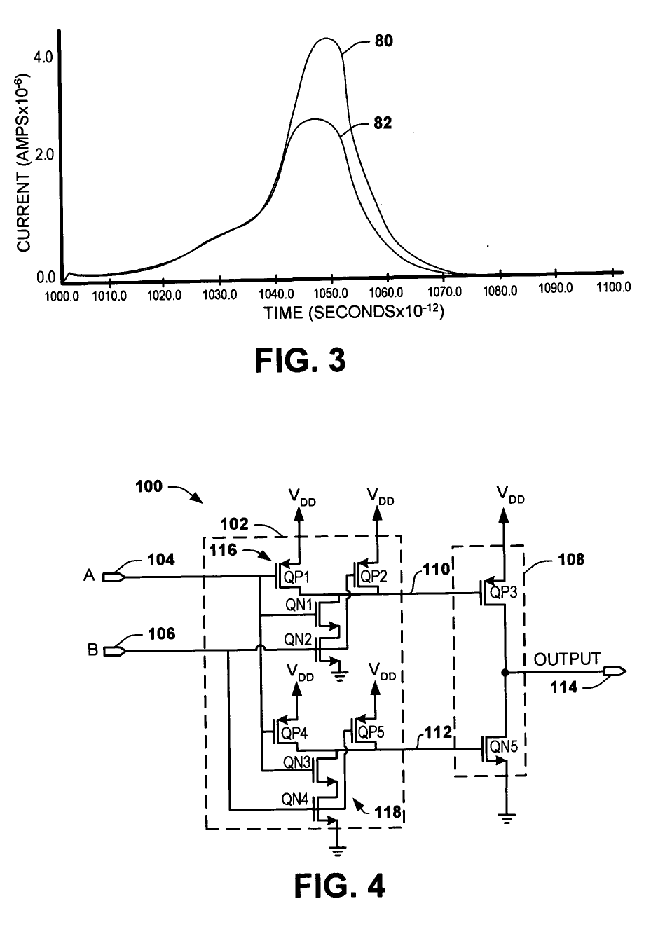

FIG. 3 depicts a comparison of switching current (in microamperes) for a conventional complementary CMOS buffer, indicated at 80, and a pseudo-push-pull CMOS buffer, indicated at 82. In the example of FIG. 3, the curves 80 and 82 correspond to supply switching current for an input signal having a 50 picosecond edge rate where both buffers drive substantially identical loads and have substantially identical capacitive loading. The respective curves 80 and 82 thus represent current consumed during an edge transition of the input signal (e.g., from low to high). From FIG. 3, it will be apparent that significantly less current is consumed by the pseudo-push-pull CMOS buffer relative to the conventional buffer. Accordingly, less switching power would also be utilized by implementing the pseudo-push-pull buffer.

FIG. 4 depicts another example of a pseudo-push pull CMOS logic circuit 100, implementing an AND function. The circuit 100 includes an input stage 102 that receives two or more input signals. In the example of FIG. 4, the input stage 102 includes a pair of inputs 104 and 106 that receive respective signals, indicated at A and B. The input stage 102 performs a logic function on the input signals A and B and drives an output stage 108 with corresponding logic signals provided at nodes 110 and 112 corresponding to inputs of the output stage. The output stage 108 in turn drives an output 114 with an OUTPUT signal based on the logic signals generated at 110 and 112.

The input stage 102 includes a pair of predriver logic paths 116 and 118. One of the predriver logic paths 116 drives the node 110 and the other predriver logic path 118 drives the other node 112 of the output stage 108. Each of the predriver logic paths 116 and 118 can be logically identical such that, in the example of FIG. 4, each path includes an arrangement of PFETs and NFETs configured to perform a NOT-AND function (i.e., A̅•̅B̅) relative to the input signals A and B. The output stage 108 is configured as a push-pull CMOS inverter that inverts the output from the input stage so that the OUTPUT corresponds to an AND function of the inputs A and B (i.e., OUTPUT=A•B).

By way of example, the predriver logic path 116 includes a pair of PFETs QP1 and QP2 connected in parallel between V_{DD} and the input 110. The inputs 104 and 106 are connected to the gates of QP1 and QP2, respectively. NFETs QN1 and QN2 are connected in series between the node 110 and electrical ground, with the inputs 104 and 106 being connected to drive the respective gates of QN1 and QN2. As a result, the predriver logic path 116 provides an inverted AND function on the inputs to provide the corresponding logic signal (i.e., A̅•̅B̅) at 110 for driving a corresponding PFET QP3 of the output stage 108.

As mentioned above, the predriver logic path 118 is logically identical to the predriver logic path 116. Thus, in the example of FIG. 4, the path 118 includes a pair of PFETs QP4 and QP5 connected in parallel between V_{DD} and the node 112. The inputs 104 and 106 are connected to the gates of QP4 and QP5, respectively. NFETs QN3 and QN4 are connected in series between the node 112 and electrical ground, with the inputs 104 and 106 are connected to drive the respective gates of QN3 and QN4. As a result, the predriver logic path 118 performs an inverted AND function (i.e., A̅•̅B̅) on the inputs to provide the corresponding logic signal at 112 for driving a corresponding NFET QN5 of the output stage 104. The output stage 108 inverts the outputs at the respective nodes 110 and 112 to provide the OUTPUT signal.

To reduce CMOS switching power, the predriver logic paths 116 and 118 can be skewed so that there is differential delay between the transitions of the logic output signals at the respective nodes 110 and 112. For instance, the skew can cause the PFET QP3 to turn off more quickly than the NFET QN5 is turned on, such as when respective nodes 110 and 112 transition from low to high. Additionally, the skew can cause NFET QN5 to turn off more quickly than the PFET QP3 turns on (i.e., the PFET turns on more slowly) at the occurrence of a high to low transition at the nodes 110 and 112. These switching latencies between the output stage FETs induce a small voltage differential between nodes 110 and 112, which mitigates crossover current significantly. The skew can be achieved by configuring the PFET to NFET width ratio of the predriver logic path 116 to be greater than the PFET to NFET width ratio of the predriver logic path 118. For example, the PFET to NFET width ratio of the predriver logic path 116 can be skewed to be greater than 2:1 (e.g., 3:1) and the PFET to NFET width ratio of the other predriver logic path 118 can be skewed to be less than 2:1 (e.g., 1:1). Other variations in the FET dimensions can also be implemented to speed-skew the respective logic paths 116 and 118.

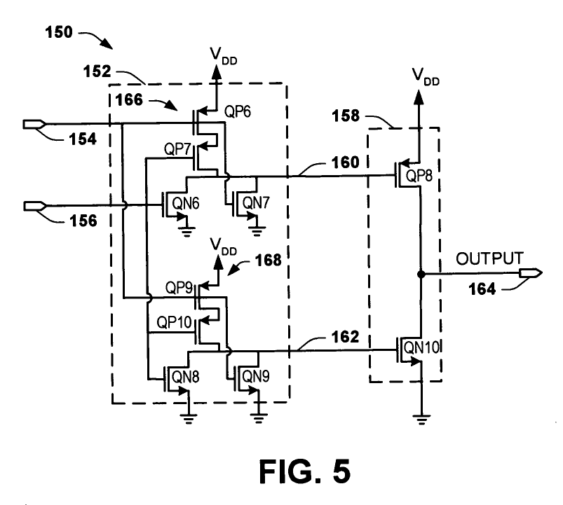

FIG. 5 depicts another example of a pseudo-push pull CMOS logic circuit 150, implementing an OR function. The circuit 150 includes an input stage 152 that receives two or more input signals, which in the example of FIG. 5 are a pair of input signals indicated at A and B received at respective inputs 154 and 156. The input stage 152 performs a logic OR function on the input signals A and B and drives an output stage 158 with corresponding logic signals provided at nodes 160 and 162 corresponding to inputs of the output stage. The output stage 158 in turn drives an output 164 with an OUTPUT signal based on the logic signals at 160 and 162, which varies as a function of the inputs A and B.

The input stage 152 includes a pair of predriver logic paths 166 and 168 electrically connected between the output stage 158 and the respective inputs 154 and 156. One of the predriver logic paths 166 drives the node 160 and the other predriver logic path 168 drives the other node 162 of the output stage 158. Each of the predriver logic paths 166 and 168 can be logically identical such that, in the example of FIG. 5, each path includes an arrangement of PFETs and NFETs configured to perform an NOT(OR) function relative to the input signals A and B (i. e., A̅+̅B̅). The output stage 158 is configured as a push-pull CMOS inverter that inverts the logic output signals at 160 and 162 from the input stage so that the OUTPUT signal corresponds to an OR function of the inputs A and B (i.e., OUTPUT=A+B)

By way of further example, the predriver logic path 166 includes a pair of PFETs QP6 and QP7 connected in series between V_{DD} and the node 160. The inputs 154 and 156 are connected to the gates of QP6 and QP7, respectively. NFETs QN6 and QN7 are connected in parallel between the node 160 and electrical ground, with the inputs 154 and 156 being connected to drive the respective gates of QN6 and QN7. The predriver logic path 166 thus performs an inverted OR function on the inputs A and B to provide the corresponding logic signal (i.e., A̅+̅B̅) at 160 for driving a corresponding PFET QP8 of the output stage 158.

As mentioned above, the predriver logic path 168 is logically identical to the predriver logic path 166. Thus, in the example of FIG. 5, the path 168 includes a pair of PFETs QP9 and QP10 connected in series between V_{DD} and the node 162. The inputs 154 and 156 are connected to drive the gates of QP9 and QP10, respectively. NFETs QN8 and QN9 are connected in parallel between the node 162 and electrical ground, with the inputs 154 and 156 being connected to drive the respective gates of QN8 and QN9. As a result, the predriver logic path 168 performs an inverted OR function ( A̅+̅B̅) on the inputs A and B to provide the corresponding logic output signal at 162 for driving a corresponding NFET QN10 of the output stage 154. The output stage 158, being a push-pull CMOS inverter, inverts the logically identical outputs at the respective nodes 160 and 162 to provide the OUTPUT signal.

To reduce CMOS switching power, the predriver logic paths 166 and 168 can be skewed so that there is delay in the transition of the logic output signals at the respective nodes 160 and 162. For instance, the skew can cause the PFET QP8 to turn off more quickly than the NFET QN10 is turned on, such as at the occurrence of a low to high transition at 160 and 162 (e.g., at the gates of QP8 and QN10). Additionally, at an opposing logic transition (e.g., a high to low transition) at 160 and 162, the skew can cause NFET QN10 to turn off more quickly than PFET QP8 turns on. In response to such switching latencies between the output stage FETs, a small voltage differential is induced between nodes 160 and 162, which mitigates crossover current significantly. The skew can be achieved by configuring the PFET to NFET width ratio of the predriver logic path 166 to be greater than the PFET to NFET width ratio of the predriver logic path 168. For example, the PFET to NFET width ratio of the predriver logic path 166 can be skewed to be greater than 2:1 and the PFET to NFET width ratio of the other predriver logic path 168 can be skewed to be less than 2:1, such as described herein. Other variations in the FET dimensions can also be implemented to speed-skew the respective logic paths 166 and 168.

From the foregoing description of various embodiments, those skilled in the art will appreciate that average switching power of various gate designs can be reduced by implementing the gate as a pseudo-push-pull CMOS gate, such as described herein. The use of pseudo-push-pull CMOS gate further can achieve further increases the power savings for IC designs operating with slower edge rates, although the approach is not limited to ICs operating at any particular edge rates.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

1. A complimentary metal oxide semiconductor (CMOS) circuit, comprising:
a CMOS output stage comprising at least one p-channel metal oxide semiconductor (PMOS) component and at least one n-channel metal oxide semiconductor (NMOS) component connected in series between first and second voltage rails, a juncture between the at least one PMOS component and at least one NMOS component providing an output; and
a predriver stage having first and second predriver paths electrically connected between at least one input and the output stage, the first predriver path being configured to perform a logic function on the at least one input to provide a first logic signal to an input of the at least one PMOS component, and the second predriver path being configured to perform the logic function on the at least one input to provide a second logic signal to an input of the at least one NMOS component; and
wherein each of the first and second predriver paths comprises at least one p-channel field effect transistor (PFET) and at least one n-channel field effect transistor (NFET) configured to perform the logic function, the first predriver path having a PFET to NFET width ratio that is different from the PFET to NFET width ratio of the second predriver path.

2. The circuit of claim 1, wherein the first predriver path having a PFET to NFET width ratio that is greater than the PFET to NFET width ratio of the second predriver path.

3. The circuit of claim 2, wherein, the PFET to NFET width ratio of the first predriver path is greater than 2:1 and the PFET to NFET width ratio of the second predriver path is less than 2:1.

4. The circuit of claim 1, wherein the output stage comprises a CMOS output driver configured to invert the first and second logic signals provided by the predriver stage.

5. The circuit of claim 1, wherein the first predriver path and the second predriver path are speed-skewed to temporarily induce a voltage differential across the inputs of the PMOS component and the NMOS component so as to mitigate crossover current in the output stage.

6. The circuit of claim 1, wherein each of the first predriver path and the second predriver path are configured as logically identical, inverting CMOS logic gates arranged to perform the logic function and provide corresponding logic signals to the respective inputs of the PMOS component and the NMOS component, such that CMOS output stage inverts the corresponding logic signals to provide a corresponding non-inverting version thereof at the output of the CMOS output stage.

7. The circuit of claim 6, wherein the logic function comprises one of a unary transfer function, an AND function, an OR function, an exclusive-OR function or a combination thereof.

8. The circuit of claim 6, wherein the output stage is a CMOS push-pull output driver configured to invert the first and second logic signals provided by the predriver stage, the PMOS component comprising a p-channel field effect transistor connected between the first voltage rail and the output, and the NMOS component comprising an n-channel field effect transistor connected between the output and the second voltage rail, the second voltage rail being less than the first voltage rail.

9. A complimentary metal oxide semiconductor (CMOS) circuit, comprising:
an output stage comprising:
a p-channel metal oxide semiconductor (PMOS) network connected between a first voltage rail and an output of the circuit to drive the output; and
an n-channel metal oxide semiconductor (NMOS) network connected in series with the PMOS network between the output and a second voltage rail to drive the output of the circuit;
an input stage having at least one input, the input stage comprising:
a first predriver logic path configured as a logic gate that is connected to provide a logic signal for driving the PMOS network according to at least one input signal provided at the at least one input; and
a second predriver logic path configured as a logic gate that is connected to provide a logic signal for driving the NMOS network according to the at least one input signal provided at the at least one input, the first predriver path having a p-channel field effect transistor (PFET) to n-channel field effect transistor (NFET) width ratio that is different from the PFET to NFET width ratio of the second predriver path so that the first predriver path is speed-skewed relative to the second predriver path.

10. The circuit of claim 9, wherein the first wherein each of the first predriver logic path and the second predriver logic path comprise logically-identical paths that are speed-skewed relative to each other such that crossover current in the output stage is mitigated.

11. The circuit of claim 10, wherein the each of the first predriver logic path and the second predriver logic path comprises a non-inverting CMOS logic gate arranged to perform the same logic function and provide corresponding logic signals to the respective inputs of the PMOS network and the NMOS network.

12. The circuit of claim 10, wherein the logic function comprises at least one of a unary transfer function, an AND function, an OR function, or an exclusive-OR function.

13. The circuit of claim 9, wherein each of the first and second predriver paths comprises at least one p-channel field effect transistor (PFET) and at least one n-channel field effect transistor (NFET) configured to perform a logic function, the first predriver path having a PFET to NFET width ratio that is greater than the PFET to NFET width ratio of the second predriver path.

14. The circuit of claim 13, wherein, the PFET to NFET width ratio of the first predriver path is greater than 2:1 and the PFET to NFET width ratio of the second predriver path is less than 2:1.

15. The circuit of claim 9, wherein the output stage is a CMOS push-pull output driver configured to invert the logic signals provided by the input stage, the PMOS component comprising a p-channel field effect transistor (PFET) connected between the first voltage rail and the output, and the NMOS component comprising an n-channel field effect transistor (NFET) connected between the output and the second voltage rail, the second voltage rail being less than the first voltage rail.

16. The circuit of claim 15, wherein each of the first and second predriver paths comprises at least one PFET and at least one NFET configured to perform the same logic function, the first predriver path having a PFET to NFET width ratio that is greater than the PFET to NFET width ratio of the second predriver path.

17. A complimentary metal oxide semiconductor (CMOS) logic circuit, comprising:
first circuit means for performing an inverting logic function on at least one input and for providing a first logic output signal;
second circuit means for performing the inverting logic function on the at least one input and for providing a second output signal;
means for inverting the first and second logic output signals and for providing a corresponding output signal that is a non-inverted version of the inverting logic function performed on the at least one input,
the first means having a p-channel field effect transistor (PFET) to n-channel field effect transistor (NFET) width ratio that is different from the PFET to NFET width ratio of the second means to induce a voltage differential at inputs of the means for inverting so as to mitigate cross-over current in the means for inverting.

18. The circuit of claim 17, wherein the first means and the second means are configured to be logically identical CMOS circuits, and speed-skewed relative to each other.

19. (canceled)

20. The circuit of claim 17, wherein each of the first and second means comprises at least one p-channel field effect transistor (PFET) and at least one n-channel field effect transistor (NFET) arranged to perform at least one of a unary transfer function, an AND function, an OR function, or an exclusive-OR function on the at least one input.

21. The circuit of claim 20, wherein the means for inverting comprises a CMOS output driver comprising:
a PFET connected between a first voltage rail and the output, the first means providing the first logic output signal to a gate of the PFET; and
an NFET connected between the output and a second voltage rail, the second means providing the second logic output signal to a gate of the NFET.

22. The system of claim 1, wherein the difference between the NFET width to PFET width ratio of the first predriver path is greater than the NFET width to PFET width ratio of the second predriver path by an amount sufficient to cause a voltage differential between the input of the input of the at least one PMOS component and the input of the at least one NMOS component so as to mitigate cross-over current in the CMOS output stage.
